(19) United States
(12) Patent Application Publication
(10) Pub. No.: US 2026/0334137 A1
(43) Pub. Date: Oct. 22, 2026

(54) HEAT TREATMENT APPARATUS AND HEAT TREATMENT METHOD

(71) Applicant: SCREEN Holdings Co., Ltd., Kyoto (JP)

(72) Inventors: Shogo SHIGEMASU, Kyoto-shi, Kyoto (JP); Kazuhiko FUSE, Kyoto-shi, Kyoto (JP); Shinji MIYAWAKI, Kyoto-shi, Kyoto (JP)

(21) Appl. No.: 19/481,855

(22) PCT Filed: Apr. 1, 2024
(86) PCT No.: PCT/JP2024/013464

§ 371 Date: Jul. 7, 2026

(30) Foreign Application Priority Data
May 15, 2023 (JP) 2023-080066

(51) Int. Cl. H10P 72/00; H10P 95/90

(52) U.S. Cl. CPC H10P 72/0436; H10P 95/90

(57) ABSTRACT

A surface of a semiconductor wafer preheated by light irradiation from a halogen lamp is irradiated with a flash of light from a flash lamp to perform flash heating. After flash heating is finished, a semiconductor wafer heated by flash light irradiation is moved up from a susceptor by an elevating mechanism, and is brought close to a shower plate to be cooled while nitrogen gas as cooling gas is ejected from a plurality of ejection holes of the shower plate. Since a distance from the shower plate ejecting nitrogen gas to the semiconductor wafer is reduced, a flow rate of nitrogen gas on the surface of the semiconductor wafer increases, heat conductivity increases, cooling efficiency of the semiconductor wafer is improved, and a high temperature fall rate can be obtained.

### TECHNICAL FIELD

The present invention relates to a heat treatment apparatus irradiating a substrate with light, thereby heating the substrate and a heat treatment method. Examples of a substrate to be treated include a semiconductor wafer, a liquid crystal display apparatus substrate, a flat panel display (FPD) substate, an optical disk substrate, a magnetic disk substrate, or a solar cell substrate.

### BACKGROUND ART

A flash lamp annealing (FLA) heating a semiconductor wafer in an extremely short time attracts attention in a manufacturing process of a semiconductor device. The flash lamp annealing is a heat treatment technique of irradiating a surface of a semiconductor wafer with a flash of light using a xenon flash lamp (a simple term of “a flash lamp” means a xenon flash lamp hereinafter), thereby increasing a temperature of only the surface of the semiconductor wafer in an extremely short time (several milliseconds or less).

A radiation spectral distribution of the xenon flash lamp ranges from an ultraviolet region to a near-infrared region, thus a wavelength of the xenon flash lamp is shorter than that of a conventional halogen lamp, and almost coincides with a basic absorption band of a silicon semiconductor wafer. Thus, when the semiconductor wafer is irradiated with a flash of light emitted from the xenon flash lamp, the temperature of the semiconductor wafer can be rapidly increased with less transmitted light. It is also known that a flash light emission for the extremely short time of several milliseconds or less can selectively increase a temperature of only a region near the surface of the semiconductor wafer.

Such a flash lamp annealing is used for a treatment requiring a heating for an extremely short time, for example, typically an activation of impurity implanted into the semiconductor wafer. When the surface of the semiconductor wafer into which the impurity is implanted by an ion implantation method is irradiated with a flash of light from the flash lamp, the surface of the semiconductor wafer can be increased to an activation temperature only for the extremely short time, thus only an impurity activation can be executed without deeply diffusing the impurity.

Disclosed as an apparatus of performing the flash lamp annealing in Patent Document 1 is an apparatus irradiating a surface of a semiconductor wafer with flash of light from a flash lamp to heat the surface for an extremely short time of one second or less after irradiating the surface with light from a halogen lamp to preheat the semiconductor wafer. When a temperature of the semiconductor wafer is reduced by natural cooling after the flash heating is finished, it takes considerable time to reduce the temperature of the semiconductor wafer to a predetermined temperature or less. In such a way, there is a possibility that improvement of throughput prevented, and moreover, an impurity activated by the flash heating may be inactivated. Thus, proposed in Patent Document 1 is a technique of supplying cooling gas such as helium gas into a chamber after the flash light irradiation to efficiently and rapidly cool the semiconductor wafer and inside the chamber.

### PRIOR ART DOCUMENTS

### Patent Document(s)

Patent Document 1: Japanese Patent Application Laid-Open No. 2021-44372

### SUMMARY

### Problem to be Solved by the Invention

However, it is difficult to obtain a sufficient temperature fall rate by merely supplying the cooling gas into the chamber. A higher temperature fall rate is required to prevent inactivation of the impurity.

The present invention is therefore has been made to solve the above problems, and it is an object to provide a heat treatment apparatus and a heat treatment method capable of improving cooling efficiency and obtaining a high temperature fall rate.

### Means to solve the problem

In order to solve the above problems, a first aspect of the present invention is a heat treatment apparatus irradiating a substrate with light to heat the substrate, including: a chamber housing a substrate; a holder holding the substrate in the chamber; a light irradiation part irradiating the substrate held by the holder with light to heat the substrate; a gas supply part supplying gas into the chamber; a perforated plate provided above the holder in the chamber and including an ejection hole through which gas supplied from the gas supply part is ejected downward; and an elevator moving up and down the substrate between a holding height position at which the substrate is held by the holder and a position more upward than the holding height position, wherein the elevator moves the substrate heated by light irradiation from the light irradiation part upward from the holder and brings the substrate close to the perforated plate to cool the substrate while cooling gas is ejected from the ejection hole of the perforated plate.

A second aspect is the heat treatment apparatus according to the first aspect, wherein a lower surface of the perforated plate includes a cylindrical body with an annular shape having a larger inner diameter than a diameter of the substrate, and the elevator moves up the substrate to an inner side of the cylindrical body to cool the substrate.

A third aspect is the heat treatment apparatus according to the first aspect, wherein a lower surface of the perforated plate includes a cylindrical body with an annular shape having a smaller inner diameter than a diameter of the substrate, and the elevator moves up the substrate to a height position close to a lower end of the cylindrical body to cool the substrate.

A fourth aspect is the heat treatment apparatus according to any one of the first to third aspects, wherein the ejection hole is formed in a position facing a center portion of the substrate supported by the elevator.

A fifth aspect is the heat treatment apparatus according to any one of the first to third aspects, wherein the ejection hole is formed in a position facing a peripheral edge portion of the substrate supported by the elevator.

A sixth aspect is the heat treatment apparatus according to the fifth aspect, wherein a discharge hole discharging gas out of the chamber is provided to an opposite side of a center of the substrate from the position where the ejection hole is formed

A seventh aspect is the heat treatment apparatus according to any one of the first to sixth aspects, further comprising a decompression part decompressing inside the chamber to less than atmospheric pressure when the substrate is cooled.

An eighth aspect is the heat treatment apparatus according to any one of the first to seventh aspects, wherein the cooling gas is nitrogen or helium.

A ninth aspect is the heat treatment apparatus according to any one of the first to eighth aspects, wherein the light irradiation part includes a flash lamp irradiating substrate with flash of light.

A tenth aspect is a heat treatment method of irradiating a substrate with light to heat the substrate, including: an irradiation step of irradiating a substrate held by a holder in a chamber with light to heat the substrate; and a cooling step of moving up the substrate which has been heated from the holder and bringing the substrate close to a perforated plate through which cooling gas is ejected from an ejection hole to cool the substrate.

An eleventh aspect is the heat treatment method according to the tenth aspect, further comprising a decompression step of decompressing inside the chamber to less than atmospheric pressure when the substrate is cooled.

A twelfth aspect is the heat treatment method according to the tenth or eleventh aspect, wherein the cooling gas is nitrogen or helium.

### Effects of the Invention

According to the heat treatment apparatus according to the first to ninth aspects, the elevator moves up the substrate heated by light irradiation from the light irradiation part from the holder and brings the substrate close to the perforated plate to cool the substrate while the cooling gas is ejected from the ejection hole of the perforated plate. Thus, a flow rate of the cooling gas on the surface of the substrate increases and heat conductivity increases, cooling efficiency of the substrate is improved, and a high temperature fall rate can be obtained.

Particularly, according to the heat treatment apparatus according to the second aspect, the lower surface of the perforated plate includes the cylindrical body with the annular shape having the larger inner diameter than the diameter of the substrate, and the elevator moves up the substrate to the inner side of the cylindrical body to cool the substrate. Thus, a flow rate of the cooling gas at a surface of the substrate can be further increased while influence of gas discharge is suppressed.

According to the heat treatment apparatus according to the tenth to twelfth aspects, the heated substrate is moved up from the holder, brought close to the perforated plate through which the cooling gas is ejected from the ejection hole, and cooled. Thus, a flow rate of the cooling gas on a surface of the substrate is increased, heat conductivity increases, cooling efficiency of the substrate is improved, and a high temperature fall rate can be obtained.

### BRIEF DESCRIPTION OF DRAWINGS

FIG. 1 is a vertical cross-sectional view illustrating a configuration of a heat treatment apparatus according to the present invention.

FIG. 2 is a perspective view illustrating an entire external appearance of a holder.

FIG. 3 is a plan view of a susceptor.

FIG. 4 is a cross-sectional view of the susceptor.

FIG. 5 is a plan view of a transfer mechanism.

FIG. 6 is a side view of the transfer mechanism.

FIG. 7 is a plan view illustrating an arrangement of a plurality of halogen lamps.

FIG. 8 is a flow chart illustrating a treatment procedure of a semiconductor wafer.

FIG. 9 is a diagram graphically illustrating a configuration of a gas ring and a shower plate.

FIG. 10 is a diagram schematically illustrating cooling of the semiconductor wafer according to the first embodiment.

FIG. 11 is a diagram schematically illustrating cooling of a semiconductor wafer according to a second embodiment.

FIG. 12 is a diagram schematically illustrating cooling of a semiconductor wafer according to a third embodiment.

FIG. 13 is a diagram schematically illustrating cooling of a semiconductor wafer according to a fourth embodiment.

FIG. 14 is a diagram schematically illustrating cooling of a semiconductor wafer according to a fifth embodiment.

### DESCRIPTION OF EMBODIMENT(S)

Embodiments according to the present invention will now be described in detail with reference to the diagrams. In the description hereinafter, unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “uniform”) include those indicating quantitatively exact equality and those in the presence of a difference within tolerance or to the extent that similar functions can be obtained. Unless otherwise noted, the expressions indicating shapes (e.g., “circular”, “rectangular”, and “cylindrical”) include those indicating geometrically exact shapes and those indicating, for example, roughness or a chamfer to the extent that similar effect can be obtained. An expression “comprising”, “including”, or “having” a certain constituent element is not an exclusive expression for excluding the presence of the other constituent elements. An expression “at least one of A, B, and C” involves “only A”, “only B”, “only C”, “arbitrary two of A, B, and C”, and “all of A, B, and C”.

### First Embodiment

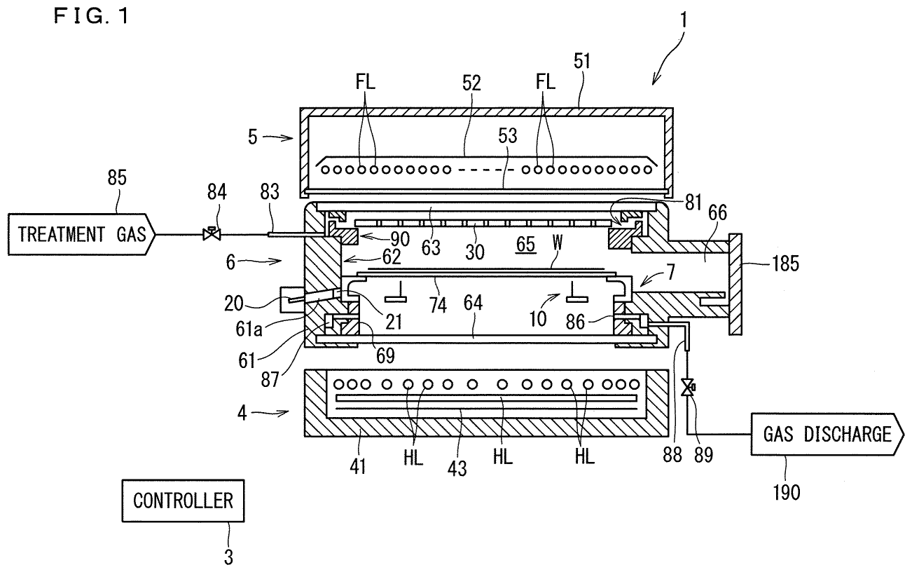

FIG. 1 is a vertical cross-sectional view illustrating a configuration of a heat treatment apparatus 1 according to the present invention. The heat treatment apparatus 1 in FIG. 1 is a flash lamp annealer for heating a disk-shaped semiconductor wafer W serving as a substrate by irradiating the semiconductor wafer W with a flash of light. A size of the semiconductor wafer W to be treated is not particularly limited. For example, the semiconductor wafer W to be treated has a diameter of 300 mm or 450 mm. An impurity is implanted into the semiconductor wafer W before being transported into the heat treatment apparatus 1, and a process of activating the implanted impurity is executed by a heat treatment in the heat treatment apparatus 1. It should be noted that dimensions of components and the number of components are illustrated in exaggeration or in simplified form, as appropriate, in FIG. 1 and the subsequent diagrams for the sake of easier understanding.

The heat treatment apparatus 1 includes a chamber 6 for housing the semiconductor wafer W, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 includes a holder 7 provided inside the chamber 6 and for holding the semiconductor wafer W in a horizontal attitude, a transfer mechanism 10 provided inside the chamber 6 and for transferring the semiconductor wafer W between the holder 7 and the outside of the heat treatment apparatus 1, and a shower plate 30. The heat treatment apparatus 1 further includes a controller 3 for controlling operation mechanisms provided to the halogen heating part 4, the flash heating part 5, and the chamber 6 to cause the operation mechanisms to execute a heat treatment on the semiconductor wafer W.

The chamber 6 is configured such that upper and lower chamber windows made of quartz are mounted to the top and bottom, respectively, of a tubular chamber side portion 61. The chamber side portion 61 has a generally tubular shape having an open top and an open bottom. An upper chamber window 63 is mounted to block the top opening of the chamber side portion 61, and a lower chamber window 64 is mounted to block the bottom opening thereof. The upper chamber window 63 forming a ceiling of the chamber 6 is a disk-shaped member made of quartz, and serves as a quartz window that transmits a flash of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

A gas ring 90 is mounted to an upper portion of the inner wall surface of the chamber side portion 61, and a reflective ring 69 is mounted to a lower portion thereof. Both the gas ring 90 and the reflective ring 69 are formed into an annular shape. An interior space of the chamber 6, i.e. a space surrounded by the upper chamber window 63, the lower chamber window 64, the chamber side portion 61, the reflective ring 69, and the gas ring 90, is defined as a heat treatment space 65.

A recessed portion 62 is formed in the inner wall surface of the chamber 6 by mounting the reflective ring 69 and the gas ring 90 to the chamber side portion 61. That is to say, formed is the recessed portion 62 surrounded by a middle portion of the inner wall surface of the chamber side portion 61 where the reflective ring 69 and the gas ring 90 are not mounted, an upper end surface of the reflective ring 69, and a lower end surface of the gas ring 90. The recessed portion 62 is formed into an annular shape in the inner wall surface of the chamber 6 in a horizontal direction, and surrounds the holder 7 holding the semiconductor wafer W.

A transport opening (throat) 66 for the transport of the semiconductor wafer W therethrough into and out of the chamber 6 is formed in the chamber side portion 61. The transport opening 66 is openable and closable by a gate valve 185. The transport opening 66 is communicably connected to an outer peripheral surface of the recessed portion 62. Thus, when the transport opening 66 is opened by the gate valve 185, the semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared radiation emitted from a lower surface of the semiconductor wafer W held by a susceptor 74 described hereinafter therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. A transparent window 21 made of barium fluoride material transparent to infrared radiation in a wavelength range measurable with the radiation thermometer 20 is mounted to an end portion of the through hole 61a which faces the heat treatment space 65.

A gas supply opening 81 for supplying treatment gas therethrough into the heat treatment space 65 is provided in the gas ring 90 attached to an upper portion of the inner wall of the chamber 6. The gas supply opening 81 is communicably connected to a gas supply pipe 83 through a flow path formed inside the gas ring 90. The gas supply pipe 83 is connected to a treatment gas supply source 85. A gas supply volve 84 is inserted at some midpoint in the gas supply pipe 83. When the gas supply valve 84 is opened, the treatment gas is supplied from the treatment gas supply source 85 to the gas ring 90, the treatment gas passing through the flow path inside the gas ring 90 is supplied from the gas supply opening 81 to the heat treatment space 65. Inert gas such as nitrogen (N₂) and helium (He), reactive gas such as hydrogen (H₂) and ammonia (NH₃), or a gas mixture thereof, for example, can be used as the treatment gas (nitrogen gas in the present embodiment).

A gas discharge hole 86 for discharging gas out of the heat treatment space 65 is provided to a lower portion of the inner wall of the chamber 6. The gas discharge opening 86 is provided below the recessed portion 62, and may be provided to the reflective ring 69. The gas discharge hole 86 is communicably connected to a gas discharge pipe 88 through a buffer space 87 formed into an annular shape inside a sidewall of the chamber 6. The gas discharge pipe 88 is connected to a gas discharge part 190. A gas discharge valve 89 is inserted at some midpoint in the gas discharge pipe 88. When the gas discharge valve 89 is opened, the gas in the heat treatment space 65 is discharged through the gas discharge hole 86 and the buffer space 87 to the gas discharge pipe 88.

The gas discharge part 190 includes a vacuum pump. Since the gas discharge part 190 is activated to discharge the gas in the heat treatment space 65 without supplying gas from the gas supply opening 81, an inside of the chamber 6 can be decompressed to less than atmospheric pressure. That is to say, the gas discharge part 190 also functions as a decompression part. The vacuum pump of the gas discharge part 190 and the gas discharge pipe 88 are connected to each other by three bypass lines having pipe diameters different from each other, for example, and when any one thereof is opened, a discharge flow amount and a discharge speed of the gas from the chamber 6 can be changed.

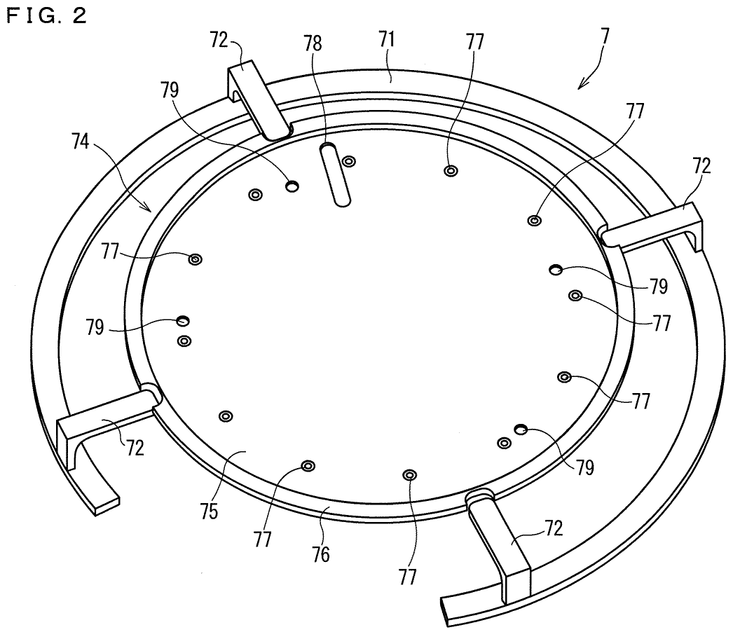

FIG. 2 is a perspective view illustrating an entire external appearance of the holder 7. The holder 7 includes a base ring 71, coupling portions 72, and the susceptor 74. The base ring 71, the coupling portions 72, and the susceptor 74 are all formed of quartz. In other words, the whole holder 7 is formed of quartz.

The base ring 71 is a quartz member having an arcuate shape obtained by removing a portion from an annular shape. This removed portion is provided to prevent interference between transfer arms 11 of the transfer mechanism 10 described hereinafter and the base ring 71. The base ring 71 is supported by a wall surface of the chamber 6 by being placed on the bottom surface of the recessed portion 62 (with reference to FIG. 1). The plurality of coupling portions 72 (in the present embodiment, four coupling portions 72) are mounted upright on the upper surface of the base ring 71 and arranged in a circumferential direction of the annular shape thereof. The coupling portions 72 are also quartz members, and are rigidly secured to the base ring 71 by welding.

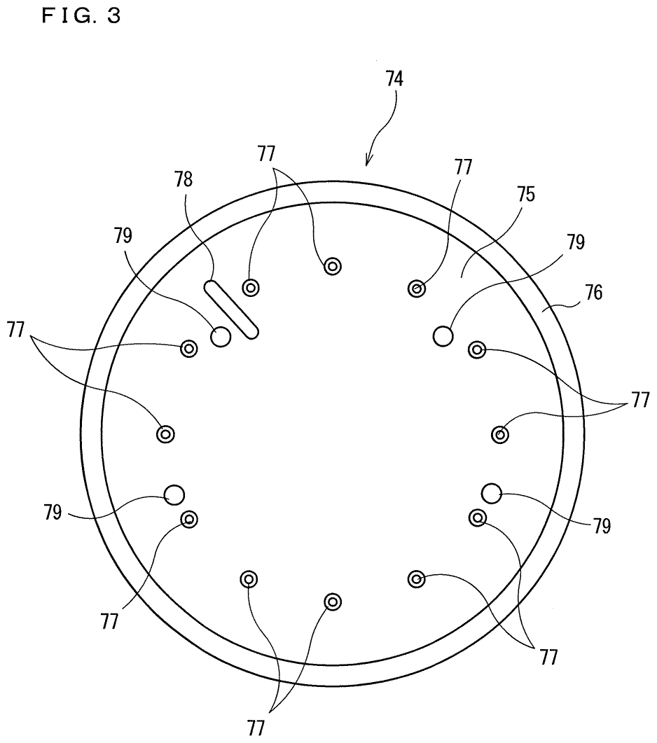

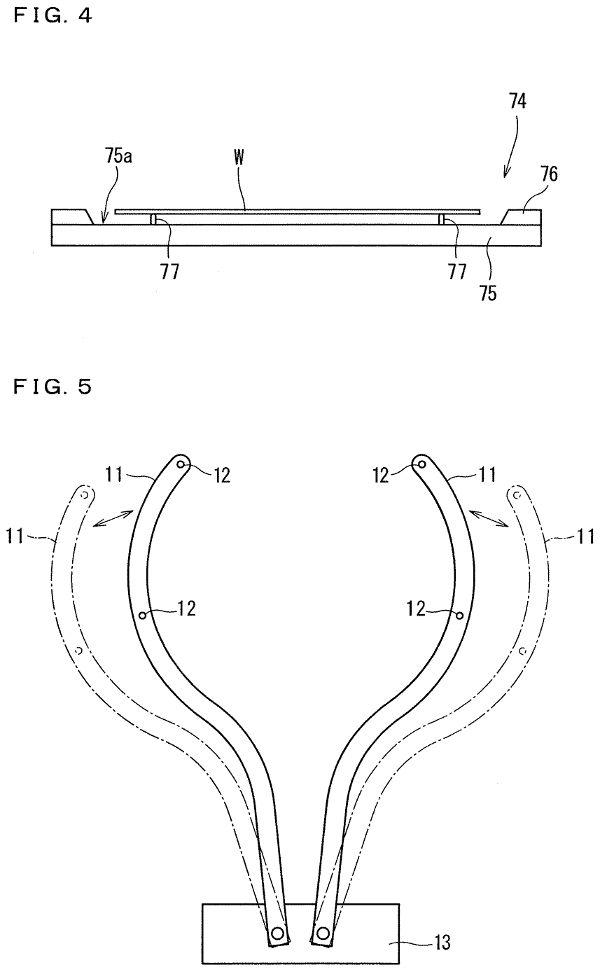

The susceptor 74 is supported by the four coupling portions 72 provided on the base ring 71. FIG. 3 is a plan view of the susceptor 74. FIG. 4 is a cross-sectional view of the susceptor 74. The susceptor 74 includes a holding plate 75, a guide ring 76, and a plurality of substrate support pins 77. The holding plate 75 is a generally circular planar member formed of quartz. A diameter of the holding plate 75 is larger than that of the semiconductor wafer W. In other words, the holding plate 75 has a size, as seen in plan view, larger than that of the semiconductor wafer W.

The guide ring 76 is provided on a peripheral edge portion of the upper surface of the holding plate 75. The guide ring 76 is an annular member having an inner diameter larger than the diameter of the semiconductor wafer W. For example, when the diameter of the semiconductor wafer W is 300 mm, the inner diameter of the guide ring 76 is 320 mm. The inner periphery of the guide ring 76 is in a form of a tapered surface which becomes wider in an upward direction from the holding plate 75. The guide ring 76 is formed of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The plurality of substrate support pins 77 are mounted upright on the holding surface 75a of the holding plate 75. In the present embodiment, a total of 12 substrate support pins 77 provided upright are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present embodiment, 270 mm) when the diameter of the semiconductor wafer W is 300 mm. Each of the substrate support pins 77 is formed of quartz. The plurality of substrate support pins 77 may be provided by welding on the upper surface of the holding plate 75 or machined integrally with the holding plate 75.

Referring again to FIG. 2, the four coupling portions 72 provided upright on the base ring 71 and the peripheral edge portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

The semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W can be supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the plurality of substrate support pins 77 is spaced a predetermined distance apart from the holding surface 75a of the holding plate 75. A thickness of the guide ring 76 is larger than the height of the substrate support pins 77. Thus, the guide ring 76 prevents the horizontal misregistration of the semiconductor wafer W supported by the plurality of substrate support pins 77.

As illustrated in FIGS. 2 and 3, an opening 78 is formed in the holding plate 75 of the susceptor 74 so as to extend vertically through the holding plate 75 of the susceptor 74. The opening 78 is provided for the radiation thermometer 20 to receive radiation (infrared radiation) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. The holding plate 75 of the susceptor 74 further includes four through holes 79 bored therein and designed so that lift pins 12 of the transfer mechanism 10 to be described later pass through the through holes 79, respectively, to transfer the semiconductor wafer W.

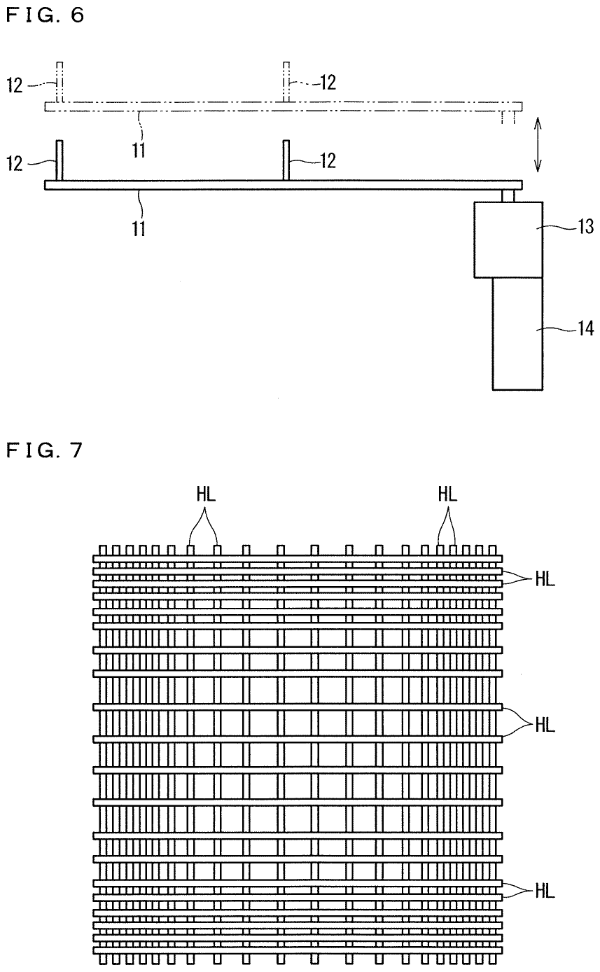

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which the semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in a plan view. The horizontal movement mechanism 13 may be of the type which causes individual motors to pivot the transfer arms 11 respectively or of the type which uses the linkage mechanism to cause a single motor to pivot the pair of transfer arms 11 in cooperative relation.

The pair of transfer arms 11 are moved up and down together with the horizontal movement mechanism 13 by an elevating mechanism 14. A pulse motor, for example, is used as the elevating mechanism 14. The elevating mechanism 14 can move up and down the pair of transfer arms 11 to an optional height position in accordance with an instruction of the controller 3. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62.

When the elevating mechanism 14 moves up the pair of transfer arms 11 while the susceptor 74 holds the semiconductor wafer W, the semiconductor wafer W is protruded upward by four lift pins 12 protruding from the through holes 79. The elevating mechanism 14 moves up and down the semiconductor wafer W between a holding height position at which the semiconductor wafer W is held by the susceptor 74 of the holder 7 and a height position more upward than the holding height position. A gas discharge mechanism not shown is also provided near the location where the drivers (the horizontal movement mechanism 13 and the elevating mechanism 14) of the transfer mechanism 10 are provided, and is configured to discharge an atmosphere around the drivers of the transfer mechanism 10 to the outside of the chamber 6.

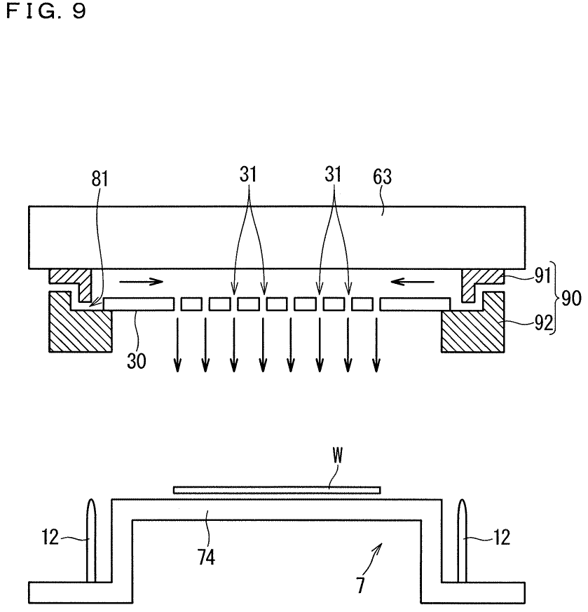

Returning to FIG. 1, the gas ring 90 and the shower plate 30 are provided to an upper portion of the chamber 6. FIG. 9 is a diagram graphically illustrating a configuration of the gas ring 90 and the shower plate 30. The gas ring 90 attached to an upper portion of the inner wall surface of the chamber side portion 61 substantially having a cylindrical shape has an annular shape. The gas ring 90 is attached so that a center thereof coincides with a center of the chamber side portion 61. That is to say, a radial direction and a circumferential direction of the gas ring 90 coincide with those of the chamber side portion 61, respectively. The gas ring 90 includes an upper ring 91 and a lower ring 92. Both of the upper ring 91 and the lower ring 92 have an annular shape. The upper ring 91 and the lower ring 92 are overlapped with each other to form the gas ring 90.

A gap is located between the upper ring 91 and the lower ring 92 in the structure that the upper ring 91 and the lower ring 92 having the annular shape are overlapped with each other. This flow path may have a labyrinth structure and a buffer which may be a resistance part for a flow of the gas. An end portion of the flow path facing inside the chamber 6 serves as the gas supply opening 81. Ane end portion on the other side of the flow path is connected to the gas supply pipe 83.

The shower plate 30 is a disk-shaped member formed of quartz. Thus, the shower plate 30 transmits the flash of light emitted from the flash heating part 5 in the manner similar to the upper chamber window 63. A plurality of ejection holes 31 are bored in the shower plate 30 to vertically pass through the shower plate 30. A size of a region where the plurality of ejection holes 31 are provided is substantially the same as that of a planar surface of the semiconductor wafer W, for example. A hole diameter of each ejection hole 31 is several millimeters. The hole diameters of the plurality of ejection holes 31 are not limited to be uniform, but may be gradually reduced from a center of the shower plate 30 toward a peripheral edge portion, for example.

The shower plate 30 having the disk-like shape is attached inside the chamber 6 while the peripheral edge portion thereof is supported by the lower ring 92 of the gas ring 90 as illustrated in FIG. 9. Thus, the shower plate 30 is provided more upward than the holder 7. When the shower plate 30 is attached inside the chamber 6, a space is formed between the upper chamber window 63 and the shower plate 30.

The treatment gas transmitted to the gas ring 90 from the treatment gas supply source 85 through the gas supply pipe 83 passes through the flow path in the gas ring 90 and is supplied to the space between the upper chamber window 63 and the shower plate 30 from the gas supply opening 81. The treatment gas is ejected downward from the plurality of ejection holes 31 provided to the shower plate 30. The treatment gas ejected in a form of shower from the shower plate 30 forms a downflow of the treatment gas downward from the upper side toward the heat treatment space 65. A total flow amount of the treatment gas ejected from the shower plate 30 is 100 L/min, for example.

Referring again to FIG. 1, the flash heating part 5 provided over the chamber 6 includes an enclosure 51, a light source provided inside an enclosure 51 and including the multiple (in the present embodiment, 30) xenon flash lamps FL, and a reflector 52 provided inside the enclosure 51 so as to cover the light source from above. The flash heating part 5 further includes a lamp light radiation window 53 mounted to a bottom of the enclosure 51. The lamp light radiation window 53 constituting the floor of the flash heating part 5 is a plate-like quartz window made of quartz. The flash heating part 5 is provided over the chamber 6, whereby the lamp light radiation window 53 is opposed to the upper chamber window 63. The flash lamps FL direct a flash of light from over the chamber 6 through the lamp light radiation window 53 and the upper chamber window 63 toward the heat treatment space 65.

The plurality of flash lamps FL, each of which is a rod-shaped lamp having an elongated cylindrical shape, are planarly arranged so that the longitudinal directions of the respective flash lamps FL are in parallel with each other along a main surface of the semiconductor wafer W held by the holder 7 (that is, in the horizontal direction). Thus, a planar surface defined by the arrangement of the flash lamps FL is also a horizontal surface. A region in which the plurality of flash lamps FL are arranged has a larger size than a size of the planar surface of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to an outer peripheral surface of the glass tube. Because the xenon gas is electrically insulative, no current flows in the glass tube in a normal state even if electrical charge is stored in the capacitor. However, if high voltage is applied to the trigger electrode to produce an electrical breakdown, electricity stored in the capacitor flows momentarily in the glass tube, and xenon atoms or molecules are excited at this time to cause light emission. This xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. That is to say, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect the flash of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present embodiment, 40) halogen lamps HL. The halogen heating part 4 directs light from under the chamber 6 through the lower chamber window 64 toward the heat treatment space 65 to heat the semiconductor wafer W by means of the halogen lamps HL.

FIG. 7 is a plan view showing an arrangement of the plurality of halogen lamps HL. The 40 halogen lamps HL are arranged in two tiers, i.e. upper and lower tiers. 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of the semiconductor wafer W held by the holding part 7 (that is, in the horizontal direction). Thus, a planar surface defined by the arrangement of the halogen lamps HL in each of the upper and lower tiers is also a horizontal surface.

As illustrated in FIG. 7, the halogen lamps HL in each of the upper and lower tiers are disposed at a higher density in a region opposed to a peripheral edge portion of the semiconductor wafer W held by the holder 7 than in a region opposed to a center portion thereof. That is to say, the halogen lamps HL in each of the upper and lower tiers are arranged at shorter intervals in the peripheral edge portion of the lamp arrangement than in the center portion thereof. This allows a larger volume of light to impinge upon the peripheral edge portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. Gas prepared by introducing a halogen element (iodine, bromine and the like) in trace amounts into inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. Thus, the halogen lamps HL are continuous lighting lamps that emit light continuously for at least not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the plurality of halogen lamps HL toward the heat treatment space 65.

The controller 3 controls the aforementioned various operation mechanisms provided to the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable-writable memory for storing various pieces of information therein, and a storage part (magnetic disk or SSD) for storing control software, data and the like therein. The CPU in the controller 3 executes a predetermined treatment program, whereby the processes in the heat treatment apparatus 1 proceed. The controller 3 controls the elevating mechanism 14 so that the semiconductor wafer W supported by the pair of transfer arms 11 is moved up and down to an optional height position within a movable range.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of the semiconductor wafer W. As an example, a water cooling tube (not shown) is provided to the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

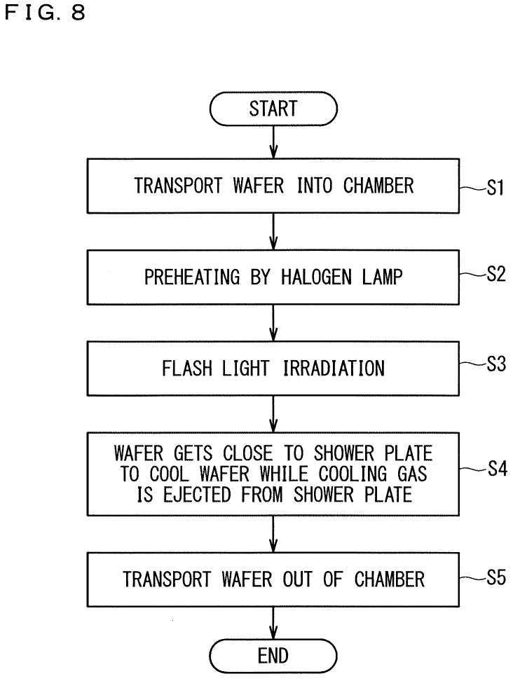

Next, a treatment procedure of the semiconductor wafer W in the heat treatment apparatus 1 will be described. FIG. 8 is a flow chart showing a treatment procedure of the semiconductor wafer W. The semiconductor wafer W to be treated herein is a semiconductor substrate to which an impurity (ion) is added by an ion implantation method. The impurity is activated by a flash irradiation heat treatment (anneal) performed by the heat treatment apparatus 1. The treatment procedure in the heat treatment apparatus 1 described hereinafter proceeds when the controller 3 controls each operation mechanism of the heat treatment apparatus 1.

Firstly, the gas supply valve 84 is opened and the gas discharge valve 89 is opened to start gas supply and discharge within the chamber 6 prior to the treatment of the semiconductor wafer W. When the gas supply valve 84 is opened, nitrogen gas is transmitted from the treatment gas supply source 85 to the gas ring 90, and is supplied to a space between the upper chamber window 63 and the shower plate 30 from the gas supply opening 81. The nitrogen gas is ejected downward from the plurality of ejection holes 31 provided to the shower plate 30. Also, when the gas discharge valve 89 is opened, the gas within the chamber 6 is discharged through the gas discharge opening 86. Accordingly, nitrogen gas ejected from the shower plate 30 flows downward to form the downflow in the heat treatment space 65.

Subsequently, the gate valve 185 is opened to open the transport opening 66. A transport robot outside the heat treatment apparatus 1 transports the semiconductor wafer W after ion implantation through the transport opening 66 into the heat treatment space 65 in the chamber 6 (Step S1). At this time, there is a possibility that the atmosphere outside the apparatus is carried into the heat treatment space 65 as the semiconductor wafer W is transported into the heat treatment space 65; however, the nitrogen gas is continuously supplied into chamber 6, thus flows through the transport opening 66, and it is possible to minimize an outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal posture from below. The semiconductor wafer W is supported by the substrate support pins 77 mounted upright on the holding plate 75, and is held by the susceptor 74. The semiconductor wafer W is held by the holder 7 in such an attitude that the front surface thereof where a pattern is formed and the impurity is implanted is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held in the horizontal attitude from below by the susceptor 74 of the holder 7 formed of quartz, the 40 halogen lamps HL in the halogen heating part 4 are turned on at the same time and preheating (or assist-heating) is started (Step S2). Halogen light emitted from the halogen lamps HL is transmitted through the lower chamber window 64 and the susceptor 74 both formed of quartz, and impinges on the lower surface of the semiconductor wafer W. By receiving irradiation with light from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured with the radiation thermometer 20 when the halogen lamps HL perform the preheating. Specifically, the radiation thermometer 20 receives infrared radiation emitted from the lower surface of the semiconductor wafer W held by the susceptor 74 through the opening 78 and passing through the transparent window 21 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured with the radiation thermometer 20. The preheating temperature T1 is set to be approximately 200 °C to 800 °C, preferably 350 °C to 600 °C, so that there is no possibility of diffusion of the impurity added to the semiconductor wafer W caused by the heat (600 °C in the present embodiment).

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured with the radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in the peripheral edge portion thereof where heat dissipation is liable to occur than in the center portion thereof. However, the halogen lamps HL in the halogen heating part 4 are disposed at a higher density in the region opposed to the peripheral edge portion of the semiconductor wafer W than in the region opposed to the center portion thereof. This causes a larger volume of light to impinge upon the peripheral edge portion of the semiconductor wafer W where heat dissipation is liable to occur, thereby providing a uniform in-plane temperature distribution of the semiconductor wafer W in the stage of preheating.

At a time when a predetermined time period has elapsed since the temperature of the semiconductor wafer W reaches the preheating temperature T1, the flash lamps FL in the flash heating part 5 irradiate the front surface of the semiconductor wafer W held by the susceptor 74 with a flash of light (Step S3). The flash of light emitted from the flash lamps FL is transmitted sequentially to the lamp light radiation window 53, the upper chamber window 63, and the shower plate 30, which are all made of quartz, impinges on the front surface of the semiconductor wafer W, and the flash heating is performed on the semiconductor wafer W.

The flash heating, which is achieved by the emission of a flash of light from the flash lamps FL, is capable of increasing the temperature of the front surface of the semiconductor wafer W in a short time. Specifically, the flash of light emitted from the flash lamps FL is an intense flash of light emitted for an extremely short period of time ranging from approximately 0.1 to 100 milliseconds as a result of the conversion of the electrostatic energy previously stored in the capacitor into such an ultrashort light pulse. The temperature of the front surface of the semiconductor wafer W is increased instantaneously to a treatment temperature T2 of 1000 °C or more by the flash irradiation from the flash lamps FL, and after the impurity implanted into the semiconductor wafer W is activated, the temperature of the front surface decreases rapidly. In this manner, the heat treatment apparatus 1 can increase and decrease the temperature of the front surface of the semiconductor wafer W in the extremely short time, thus the diffusion of the impurity implanted into the semiconductor wafer W caused by the heat can be suppressed and the impurity can be activated. The time required for the activation of the impurity is extremely shorter than the time required for a heat diffusion; thus, the activation is completed in a short time of approximately 0.1 milliseconds to 100 milliseconds in which the diffusion does not occur.

When the preheating and the flash heating of the semiconductor wafer W are executed, as illustrated in FIG. 9, nitrogen gas is ejected downward from the shower plate 30 while the semiconductor wafer W is held by the susceptor 74. Since an interval between the shower plate 30 and the semiconductor wafer W held by the susceptor 74 is relatively large, there is no risk of decrease of the temperature of semiconductor wafer W, which is being heated, by nitrogen gas ejected from the shower plate 30.

When the flash heating treatment is finished, the halogen lamps HL are turned off after an elapse of a predetermined time. The controller 3 controls the driver of the transfer mechanism 10 so that the pair of transfer arms 11 is horizontally moved from the retracted position to the transfer operation position, and is then moved up. Accordingly, the lift pins 12 protrudes from the upper surface of the susceptor 74 and receives the semiconductor wafer W after the heat treatment from the susceptor 74. Then, the elevating mechanism 14 moves up the lift pins 12, brings the semiconductor wafer W close to the shower plate 30, and cools the semiconductor wafer W while nitrogen gas as cooling gas is ejected from the plurality of ejection holes 31 of the shower plate 30 (Step S4).

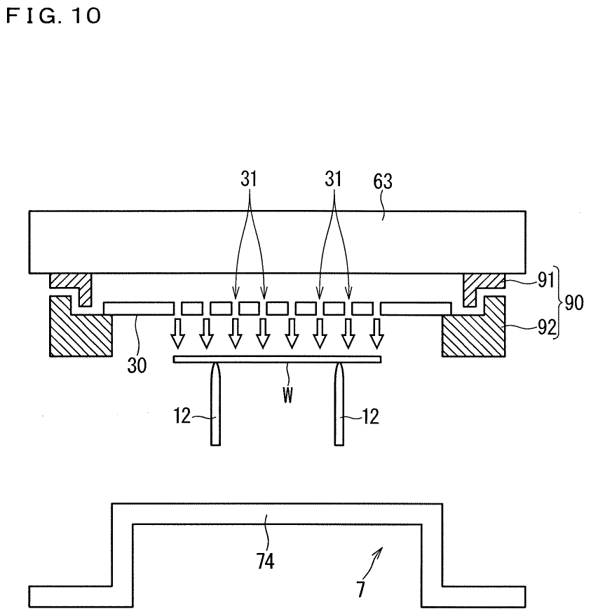

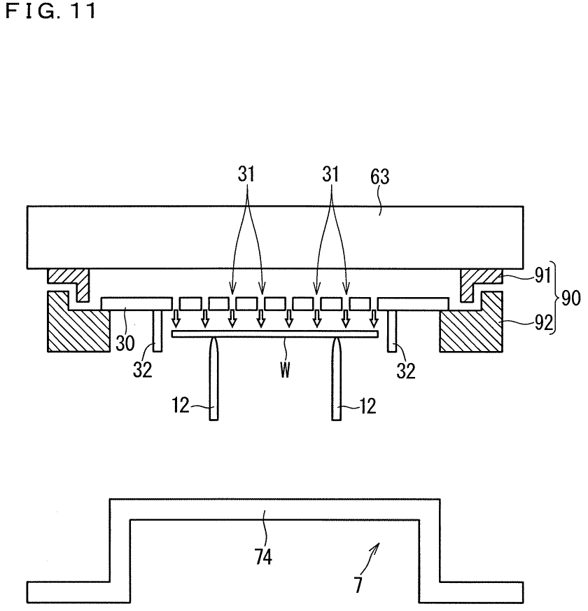

FIG. 10 is a diagram schematically illustrating cooling of the semiconductor wafer W according to the first embodiment. The elevating mechanism 14 moves up the lift pins 12 and brings the semiconductor wafer W immediately below the shower plate 30 under control of the controller 3. The semiconductor wafer W is moved up to the height position where an interval between the semiconductor wafer W and the shower plate 30 is equal to or smaller than 10 mm, for example. When the semiconductor wafer W is brought close to the shower plate 30 while nitrogen gas is ejected from the plurality of ejection holes 31 of the shower plate 30, the ejected nitrogen gas is directly blown onto the semiconductor wafer W and flows along the front surface of the semiconductor wafer W, and a flow rate of nitrogen gas on the front surface thereof increases. Accordingly, heat conductivity from the semiconductor wafer W to nitrogen gas increases, cooling efficiency of the semiconductor wafer W is improved, and a high temperature fall rate can be obtained.

When the temperature of the semiconductor wafer W is decreased by natural cooling (open cooling) after the flash heating is finished, a high temperature fall rate cannot be obtained, and the semiconductor wafer W is left in a temperature range in which the impurity is inactivated for a long time. Then, a problem that the impurity activated by the flash heating is inactivated occurs. In the first embodiment, the semiconductor wafer W is brought close to the shower plate 30 ejecting nitrogen gas, cooling efficiency of the semiconductor wafer W is improved, and a high temperature fall rate is obtained. Thus, the semiconductor wafer W rapidly passes through the inactivation temperature range, and inactivation of the impurity activated by the flash heating can be suppressed.

After the semiconductor wafer W is cooled, the elevating mechanism 14 moves down the lift pins 12 to move the semiconductor wafer W to a passing position. This passing position is a height position between the cooling height position of the semiconductor wafer W close to the shower plate 30 and the holding height position of the semiconductor wafer W held by the susceptor 74. Subsequently, the transport opening 66 which has been closed is opened by the gate valve 185, and the transport robot outside the heat treatment apparatus 1 transports the semiconductor wafer W placed on the lift pins 12 to the outside. Thus, the heat treatment apparatus 1 completes the heating treatment of the semiconductor wafer W (Step S5).

In the first embodiment, the semiconductor wafer W heated by the flash light irradiation is moved up from the susceptor 74 by the elevating mechanism 14, and is brought close to the shower plate 30 to be cooled while nitrogen gas as the cooling gas is ejected from the plurality of ejection holes 31 of the shower plate 30. Since the distance from the shower plate 30 ejecting nitrogen gas to the semiconductor wafer W is reduced, a flow rate of nitrogen gas on the front surface of the semiconductor wafer W increases, heat conductivity increases, cooling efficiency of the semiconductor wafer W is improved, and a high temperature fall rate can be obtained. As a result, inactivation of the impurity can be suppressed, and a treatment time is reduced and throughput can be improved.

### Second Embodiment

Next, a second embodiment of the present invention will be described. A whole configuration of the heat treatment apparatus according to the second embodiment is substantially similar to that of the first embodiment (FIG. 1). The treatment procedure of the semiconductor wafer W in the second embodiment is also the same as that in the first embodiment (FIG. 8). The second embodiment is different from the first embodiment in that a ring is provided to the shower plate 30.

FIG. 11 is a diagram schematically illustrating cooling of the semiconductor wafer W according to the second embodiment. A ring 32 is attached to a lower surface of the shower plate 30 according to the second embodiment. The ring 32 according to the second embodiment is a cylindrical body with an annular shape having an inner diameter larger than the diameter of the semiconductor wafer W. In other words, the ring 32 is a cylindrical member having an inner diameter larger than the diameter of the semiconductor wafer W. Accordingly, the semiconductor wafer W can be moved up to an inner side of the ring 32 having a relatively large inner diameter. When the diameter of the semiconductor wafer W is 300 mm, the inner diameter of the ring 32 is 320 mm to 330 mm, for example.

The ring 32 is formed of quartz in the manner similar to the shower plate 30. The plurality of ejection holes 31 are formed in an inner region of the ring 32 in the shower plate 30.

In the second embodiment, after the flash heating treatment is finished, the elevating mechanism 14 moves up the lift pins 12 and moves the semiconductor wafer W to the inner side of the ring 32 to cool the semiconductor wafer W while nitrogen gas is ejected from the plurality of ejection holes 31 of the shower plate 30. Since the semiconductor wafer W is moved up to the inner side of the ring 32 as the cylindrical member, nitrogen gas ejected from the ejection hole 31 is blown to the semiconductor wafer W more intensively, the flow rate of nitrogen gas on the front surface of the semiconductor wafer W is further increased more than the first embodiment. As a result, cooling efficiency of the semiconductor wafer W is improved, and a high temperature fall rate can be obtained.

When the semiconductor wafer W is put inside the ring 32 having the cylindrical shape and is cooled, influence of gas discharge from the gas discharge hole 86 is suppressed, and a uniform nitrogen gas flow can be formed on the front surface of the semiconductor wafer W. That is to say, a rectification action can be obtained by the ring 32. Accordingly, the temperature of the whole surface of the semiconductor wafer W can be reduced at a uniform temperature fall rate.

### Third Embodiment

Next, a third embodiment of the present invention will be described. A whole configuration of the heat treatment apparatus according to the third embodiment is substantially similar to that of the first embodiment (FIG. 1). The treatment procedure of the semiconductor wafer W in the third embodiment is also the same as that in the first embodiment (FIG. 8). The third embodiment is different from the first embodiment in that a ring is provided to the shower plate 30. However, a size of the ring is different between the second and third embodiments.

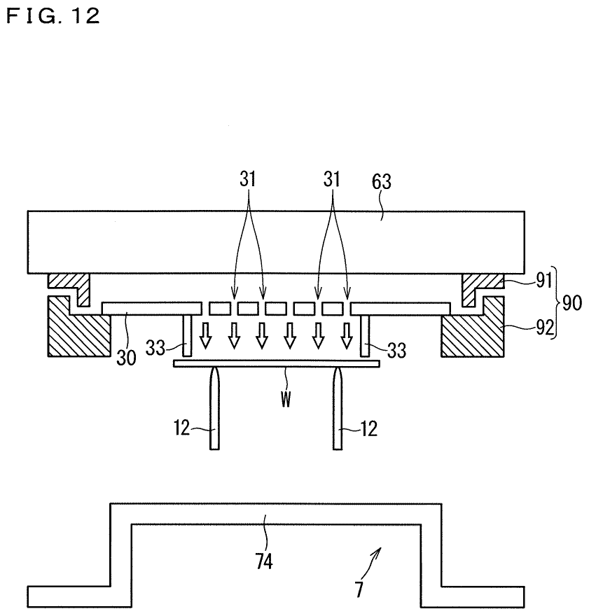

FIG. 12 is a diagram schematically illustrating cooling of the semiconductor wafer W according to the third embodiment. A ring 33 is attached to the lower surface of the shower plate 30 according to the third embodiment. The ring 33 according to the third embodiment is a cylindrical body with an annular shape having an inner diameter smaller than the diameter of the semiconductor wafer W. In other words, the ring 33 is a cylindrical member having an inner diameter smaller than the diameter of the semiconductor wafer W. Differing from the second embodiment, the semiconductor wafer W cannot be put inside the ring 33 having a relatively small inner diameter. When the diameter of the semiconductor wafer W is 300 mm, the inner diameter of the ring 33 is 270 mm to 280 mm, for example.

The ring 33 is formed of quartz in the manner similar to the shower plate 30. The plurality of ejection holes 31 are formed in an inner region of the ring 33 in the shower plate 30.

In the third embodiment, after the flash heating treatment is finished, the elevating mechanism 14 moves up the lift pins 12 and moves up the semiconductor wafer W to a height position close to a lower end of the ring 33 to cool the semiconductor wafer W while nitrogen gas is ejected from the plurality of ejection holes 31 of the shower plate 30. When the semiconductor wafer W is moved up to the height position, the lower end of the ring 33 gets close to the peripheral edge portion of the semiconductor wafer W with a minute interval therebetween. However, the lower end of the ring 33 does not have contact with the peripheral edge portion of the semiconductor wafer W. Also according to such a configuration, since nitrogen gas ejected from the plurality of ejection holes 31 wholly passes through inside the ring 33 and is blown to the semiconductor wafer W, thus is blown to the semiconductor wafer W more intensively. The flow rate of nitrogen gas on the front surface of the semiconductor wafer W is further increased more than the first embodiment. As a result, cooling efficiency of the semiconductor wafer W is improved, and a high temperature fall rate can be obtained.

### Fourth Embodiment

Next, a fourth embodiment of the present invention will be described. A whole configuration of the heat treatment apparatus according to the fourth embodiment is substantially similar to that of the first embodiment (FIG. 1). The treatment procedure of the semiconductor wafer W in the fourth embodiment is also the same as that in the first embodiment (FIG. 8). The fourth embodiment is different from the first embodiment in a configuration of the shower plate 30.

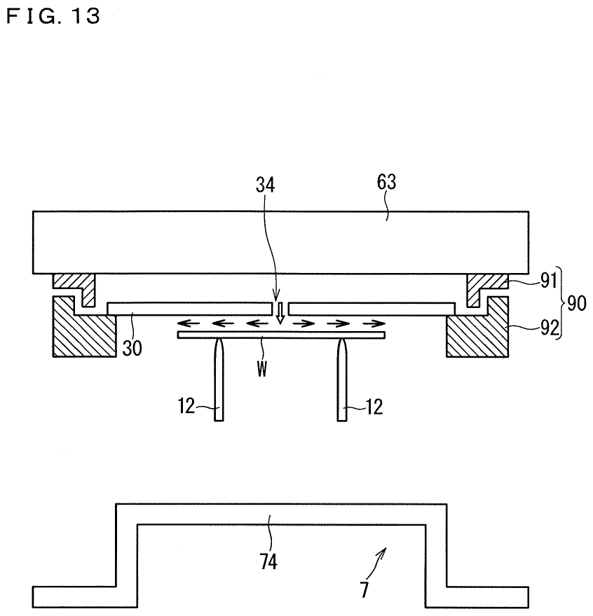

FIG. 13 is a diagram schematically illustrating cooling of the semiconductor wafer W according to the fourth embodiment. Although the plurality of ejection holes 31 are provided to the shower plate 30 in the first to third embodiments, one ejection hole 34 is bored in the center of the shower plate 30 in the fourth embodiment. More exactly, one ejection hole 34 is bored in a position in the shower plate 30 facing a center portion of the semiconductor wafer W supported by the lift pins 12. A hole diameter of the ejection hole 34 may be larger than a hole diameter of the ejection hole 31.

In the fourth embodiment, after the flash heating is finished, the elevating mechanism 14 moves up the lift pins 12, brings the semiconductor wafer W close to the shower plate 30, and cools the semiconductor wafer W while nitrogen gas is ejected downward from the ejection hole 34 in the center of the shower plate 30. As illustrated in FIG. 13, nitrogen gas ejected from the ejection hole 34 is blown to the center portion of the semiconductor wafer W, and flows to spread from the center portion toward the peripheral edge portion. Also according to such a configuration, the flow rate of nitrogen gas on the front surface of the semiconductor wafer W increases, heat conductivity increases, cooling efficiency of the semiconductor wafer W is improved, and a high temperature fall rate can be obtained.

Since nitrogen gas blown to the center portion of the semiconductor wafer W flows toward the peripheral edge portion, uniform nitrogen gas flow can be formed on the front surface of the semiconductor wafer W. Accordingly, the temperature of the whole surface of the semiconductor wafer W can be reduced at a uniform temperature fall rate.

### Fifth Embodiment

Next, a fifth embodiment of the present invention will be described. A whole configuration of the heat treatment apparatus according to the fifth embodiment is substantially similar to that of the first embodiment (FIG. 1). The treatment procedure of the semiconductor wafer W in the fifth embodiment is also the same as that in the first embodiment (FIG. 8). The fifth embodiment is different from the first embodiment in a configuration of the shower plate 30.

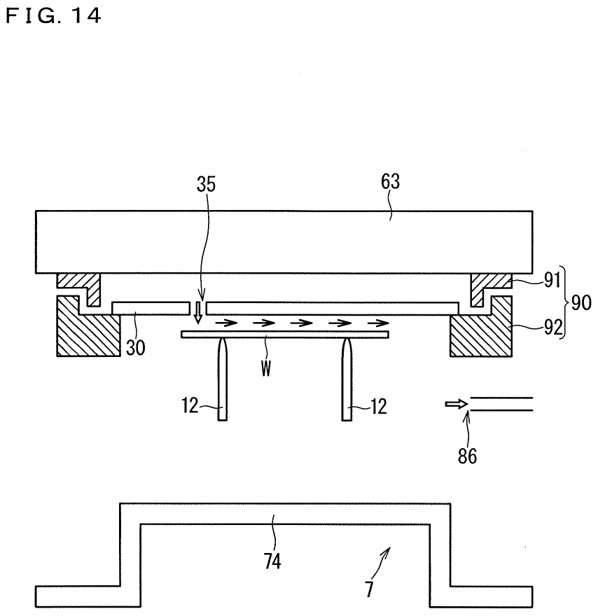

FIG. 14 is a diagram schematically illustrating cooling of the semiconductor wafer W according to the fifth embodiment. In the fifth embodiment, one ejection hole 35 is bored in an end portion of the shower plate 30. More exactly, one ejection hole 35 is bored in a position in the shower plate 30 facing the peripheral edge portion of the semiconductor wafer W supported by the lift pins 12. A hole diameter of the ejection hole 35 may be larger than the hole diameter of the ejection hole 31.

In the fifth embodiment, adjusted is a position of providing the gas discharge hole 86 discharging gas out of the chamber 6. Specifically, in a plan view of the chamber 6 seen from the upper side, the gas discharge hole 86 is provided to an opposite side of the center of the semiconductor wafer W supported by the lift pins 12 from the ejection hole 35 of the shower plate 30. A height position of providing the gas discharge hole 86 can be appropriately set.

In the fifth embodiment, after the flash heating is finished, the elevating mechanism 14 moves up the lift pins 12, brings the semiconductor wafer W close to the shower plate 30, and cools the semiconductor wafer W while nitrogen gas is ejected downward from the ejection hole 35 in the end portion of the shower plate 30. As illustrated in FIG. 14, nitrogen gas ejected from the ejection hole 35 is blown to one side of the peripheral edge portion of the semiconductor wafer W, and flows to spread from one side toward the other side of the peripheral edge portion. The other side of the peripheral edge portion herein is the opposite side of the center of the semiconductor wafer W from one side of the peripheral edge portion described above.

In the fifth embodiment, the gas discharge hole 86 is provided to the opposite side of the center of the semiconductor wafer W from the ejection hole 35. Thus, when nitrogen gas is discharged from the gas discharge hole 86, a flow of nitrogen gas from one side toward the other side of the peripheral edge portion of the semiconductor wafer W described above is formed more easily. That is to say, formation of flow of nitrogen gas from one side toward the other side of the peripheral edge portion of the semiconductor wafer W is supplemented by discharge from the gas discharge hole 86.

When the flow of nitrogen gas from one side toward the other side of the peripheral edge portion of the semiconductor wafer W along the front surface thereof as with the fifth embodiment, the flow rate of nitrogen gas on the front surface of the semiconductor wafer W increases, heat conductivity increases, cooling efficiency of the semiconductor wafer W is improved, and a high temperature fall rate can be obtained. Since the flow of nitrogen gas in substantially one direction from one side toward the other side of the peripheral edge portion of the semiconductor wafer W is formed in the fifth embodiment, accumulation of nitrogen gas hardly occurs.

### Sixth Embodiment

Next, a sixth embodiment of the present invention will be described. A whole configuration of the heat treatment apparatus according to the sixth embodiment is substantially similar to that of the first embodiment (FIG. 1). The treatment procedure of the semiconductor wafer W in the sixth embodiment is also the same as that in the first embodiment (FIG. 8). In the sixth embodiment, the inside of the chamber 6 is decompressed during cooling the semiconductor wafer W.

A configuration of the shower plate 30 according to the sixth embodiment is the same as that according to any of the first to fifth embodiments. That is to say, at least one ejection hold is bored in the shower plate 30. A ring may be provided to the shower plate 30.

In the sixth embodiment, after the flash heating is finished, the elevating mechanism 14 moves up the lift pins 12, brings the semiconductor wafer W close to the shower plate 30, and cools the semiconductor wafer W while nitrogen gas is ejected downward from the ejection hole provided to the shower plate 30. In addition, in the sixth embodiment, the exhaust part 190 discharges gas in the chamber 6 from the gas discharge hole 86 to decompress inside the chamber 6 to less than atmospheric pressure. Nitrogen gas is ejected into the chamber 6 and gas is discharged in the chamber 6. Thus, although it is difficult to decompress inside the chamber 6 to a high vacuum state, it is possible to decompress inside the chamber 6 to less than atmospheric pressure (for example, approximately 5000 Pa) by making a gas discharge flow amount get larger than a supply frow amount of nitrogen gas.

Since the semiconductor wafer W is brought close to the shower plate 30 ejecting nitrogen gas and the inside of the chamber 6 is decompressed to less than atmospheric pressure, the flow rate of nitrogen gas on the front surface of the semiconductor wafer W can be further increased. As a result, heat conductivity to nitrogen gas increases, cooling efficiency of the semiconductor wafer W is improved, and a high temperature fall rate can be obtained.

### Modification Example

While the embodiments according to the present invention have been described hereinabove, various modifications of the present invention are possible in addition to those described above without departing from the scope and spirit of the present invention. Although nitrogen gas is ejected as cooling gas from the shower plate 30 in each embodiment described above, for example, the configuration is not limited thereto. Helium gas or hydrogen gas having high heat conductivity may be used as the cooling gas, for example. Since helium gas or hydrogen gas having higher heat conductivity than nitrogen gas is used as cooling gas, cooling efficiency of the semiconductor wafer W can be further improved. Since nitrogen gas is significantly inexpensive than helium gas or hydrogen gas, increase of running cost can be suppressed by using nitrogen gas as cooling gas.

A plurality of ejection holes may be provided to the shower plate 30 in the fourth embodiment and the fifth embodiment. That is to say, the plurality of ejection holes 34 may be provided to the center of the shower plate 30 in the fourth embodiment. The plurality of ejection holes 35 may be provided to the end portion of the shower plate 30 in the fifth embodiment.

The second embodiment and the fourth or fifth embodiment may be applied together. That is to say, it is also applicable that a ring having a larger diameter than the semiconductor wafer W is provided to the lower surface of the shower plate 30, and one ejection hole is provided to a center or an end portion of an inner region of the ring.

An interval between the semiconductor wafer W and the shower plate 30 when the semiconductor wafer W is brought close to the shower plate 30 can be set to have an appropriate value. As the interval between the shower plate 30 and the semiconductor wafer W decreases, the flow rate of nitrogen gas on the front surface of the wafer is increased, and cooling efficiency can be improved. However, there is increasing concern that particles adhere to the surface thereof. There is a case where a relatively lower temperature fall rate than that in each embodiment described above is preferable depending on contents of the process in the heat treatment apparatus 1. In such a case, it is preferable to bring the semiconductor wafer W close to the shower plate 30 at an interval achieving a necessary temperature fall rate.

It is also possible to appropriately adjust the position of providing the gas discharge hole 86 discharging gas out of the chamber 6. A direction of the flow of nitrogen gas formed on the front surface of the semiconductor wafer W in cooling the semiconductor wafer W can be adjusted by the position of providing the gas discharge hole 86 (when the ring is provided as described in the second embodiment and the third embodiment, the nitrogen gas flow is not influenced by the gas discharge hole 86). Accordingly, it is preferable to provide the gas discharge hole 86 in a position where a flow of nitrogen gas capable of increasing cooling efficiency the most is formed. Thus, in the fifth embodiment, the gas discharge hole 86 is provided to the opposite side of the center of the semiconductor wafer W from the ejection hole 35

Adjustment of the position of the gas discharge hole 86 is not necessary in the fifth embodiment. The flow of nitrogen gas along the front surface of the semiconductor wafer W can be formed by ejecting nitrogen gas from the ejection hole 35 in the end portion of the shower plate 30 as with the fifth embodiment regardless of the position of the gas discharge hole 86. When the gas discharge hole 86 is provided to the opposite side of the center of the semiconductor wafer W from the ejection hole 35, the flow of nitrogen gas from one side toward the other side of the peripheral edge portion of the semiconductor wafer W can be formed more reliably.

A timing at which the elevating mechanism 14 moves up the lift pins 12 is not limited to a timing after the flash light irradiation, but may be substantially the same timing as the flash light irradiation. Since the flash of light is emitted from the flash lamps FL for an extremely short period of time ranging from approximately 0.1 to 100 milliseconds, the front surface temperature of the semiconductor wafer W reaches the treatment temperature T2 as a target temperature even when the lift pins 12 are moved up at substantially the same time as the flash light irradiation. When the lift pins 12 are moved up at substantially the same time as the flash light irradiation, the semiconductor wafer W after being heated can be rapidly cooled.

Although the 30 flash lamps FL are provided to the flash heating part 5 according to each embodiment described above, the present invention is not limited thereto. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In each embodiment described above, the filament-type halogen lamps HL are used as continuous lighting lamps that emit light continuously for not less than one second to preheat the semiconductor wafer W. The present invention, however, is not limited thereto. In place of the halogen lamps HL, discharge type arc lamps (e.g., xenon arc lamps) or LED lamps may be used as continuous lighting lamps to perform the preheating.

### EXPLANATION OF REFERENCE SIGNS

1 heat treatment apparatus
3 controller
4 halogen heating part
5 flash heating part
6 chamber
7 holder
10 transfer mechanism
12 lift pin
14 elevating mechanism
30 shower plate
31, 34, 35 ejection hole
32, 33 ring
61 chamber side portion
65 heat treatment space
74 susceptor
81 gas supply opening
84 gas supply valve
85 treatment gas supply source
86 gas discharge hole
89 gas discharge valve
90 gas ring
92 lower ring
190 gas discharge part
FL flash lamp
HL halogen lamp
W semiconductor wafer

1. A heat treatment apparatus heating a substrate by irradiating the substrate with light, comprising:
a chamber housing a substrate;
a holder holding the substrate in the chamber;
a light irradiation part irradiating the substrate held by the holder with light to heat the substrate;
a gas supply part supplying gas into the chamber;
a perforated plate provided above the holder in the chamber and including an ejection hole through which gas supplied from the gas supply part is ejected downward; and
an elevator moving up and down the substrate between a holding height position at which the substrate is held by the holder and a position more upward than the holding height position, wherein
the elevator moves the substrate heated by light irradiation from the light irradiation part upward from the holder and brings the substrate close to the perforated plate to cool the substrate while cooling gas is ejected from the ejection hole of the perforated plate.

2. The heat treatment apparatus according to claim 1, wherein
a lower surface of the perforated plate includes a cylindrical body with an annular shape having a larger inner diameter than a diameter of the substrate, and
the elevator moves up the substrate to an inner side of the cylindrical body to cool the substrate.

3. The heat treatment apparatus according to claim 1, wherein
a lower surface of the perforated plate includes a cylindrical body with an annular shape having a smaller inner diameter than a diameter of the substrate, and
the elevator moves up the substrate to a height position close to a lower end of the cylindrical body to cool the substrate.

4. The heat treatment apparatus according to claim 1, wherein
the ejection hole is formed in a position facing a center portion of the substrate supported by the elevator.

5. The heat treatment apparatus according to claim 1, wherein
the ejection hole is formed in a position facing a peripheral edge portion of the substrate supported by the elevator.

6. The heat treatment apparatus according to claim 5, wherein
a discharge hole discharging gas out of the chamber is provided to an opposite side of a center of the substrate from the position where the ejection hole is formed.

7. The heat treatment apparatus according to claim 1, further comprising
a decompression part decompressing inside the chamber to less than atmospheric pressure when the substrate is cooled.

8. The heat treatment apparatus according to claim 1, wherein
the cooling gas is nitrogen or helium.

9. The heat treatment apparatus according to claim 1, wherein
the light irradiation part includes a flash lamp irradiating substrate with flash of light.

10. A heat treatment method of irradiating a substrate with light to heat the substrate, comprising:
irradiating a substrate held by a holder in a chamber with light to heat the substrate; and
moving up the substrate which has been heated from the holder and bringing the substrate close to a perforated plate through which cooling gas is ejected from an ejection hole to cool the substrate.

11. The heat treatment method according to claim 10, further comprising
decompressing inside the chamber to less than atmospheric pressure when the substrate is cooled.

12. The heat treatment method according to claim 10, wherein
the cooling gas is nitrogen or helium.
